(19) United States
(12) Patent Application Publication
(10) Pub. No.: US 2023/0002670 A1
(43) Pub. Date: Jan. 5, 2023

(54) LUMINESCENT OPTICAL DEVICE AND ILLUMINATING INK COMPOSITION

(71) Applicant: Lusoco B.V., EINDHOVEN (NL)

(72) Inventor: Jeroen ter Schiphorst, EINDHOVEN (NL)

(21) Appl. No.: 17/778,681

(22) PCT Filed: Nov. 19, 2020
(86) PCT No.: PCT/IB2020/060913

§ 371 Date: May 20, 2022

(30) Foreign Application Priority Data
Nov. 22, 2019 (NL) 2024294

(51) Int. Cl. C09K 11/06; F21V 8/00; C09D 11/30; C09D 11/322; C09K 11/02

(52) U.S. Cl. CPC C09K 11/06; G02B 6/0003; C09D 11/30; C09D 11/322; C09K 11/02; C09K 2211/1018

(57) ABSTRACT

A luminescent optical device, comprising an optical substrate that provides a wave guide, and an illuminating ink composition are disclosed. The device comprises a cured layer of said ink composition at an interface of said waveguide, substantially comprising a polymer matrix and a luminescence agent that is dispersed in said polymer matrix. The ink composition comprises a polymerizable acrylate compound, particularly a poly-di-acrylate matrix, preferably a poly-glycol di-acrylate matrix. The ink composition further contains a polymerization initiator that is configured and capable of releasing free radicals during polymerization of said acrylate compound and a polymerization promoter that comprises a thiol compound.

The present invention relates to a luminescent optical device, comprising an optical substrate that provides a wave guide and a luminescent composition that is provided at an interface of said waveguide, wherein said luminescent composition substantially comprises a polymer matrix and a luminescence agent that is dispersed in said polymer matrix. The invention moreover relates to an illuminating ink composition that is particularly suitable for a luminescent optical device, referred to hereinbefore.

A luminescent optical device as described in the opening paragraph may be employed as a so called luminescent solar concentrator (LSC) device. An LSC allows collecting sunlight over a larger area and concentrating it on a relatively small area where the sunlight is concentrated along the edges of the device. One or more solar cells are applied at the edges of the LSC to convert the concentrated sunlight into electricity. An LSC typically comprises a glass or plastic waveguide coated or doped with highly emissive fluorophores. Direct and diffused sunlight is absorbed by a fluorophore and re-emitted at a longer wavelength. The luminescence propagates to the waveguide edges by total internal reflection and is converted into electricity by high-efficiency PV cells installed along the slab perimeter. Since the surface of the slab exposed to sunlight can be much larger than the surface of its edges, the LSC effectively increases the photon density incident onto the PV cell, which can boost its photo current.

Another application of the present invention is in illuminating surfaces. In this case the substrate provides a wave guide for incident light from one or more light sources that are provided along one or more of the edges of said substrate. A fraction of said light will manage to escape from the waveguide at said optical interface where in will excite the luminescent composition at said interface, causing it to illuminate at a distinct colour.

LSC's can be used in small and large scale projects independently of the angle and direction of the surface with relation to the sun, as it works efficiently at indirect and direct sunlight. LSC's come in a variety of colours, shapes, and transparencies, rendering the application of an LSC flexible for design choices when integrating them into the sides of buildings. In the near future, building integrated photovoltaics (PV) could revolutionize urban architecture by allowing one to reach the ambitious goal of net zero energy consumption buildings. Luminescent solar concentrators (LSCs) can play an important role in this transition. For example, semitransparent PV windows comprising LSCs could convert the energy passive facades of urban buildings into distributed energy generation units. Other applications could be signage, light boxes, bus stops and automotive wind screens.

A known luminescent solar concentrator is described in US patent application US 2016/0380140. In some case the luminescent composition of this known device is the waveguide; in others the polymer is applied as a coating of a waveguide. In the latter case the waveguide is provided by a transparent sheet, typically of poly-methyl-methacrylate (PMMA) or glass, that is coated by a film comprising the luminescent composition. The known luminescent composition comprises a polymer matrix or sol-gel and up to 10 wt % luminescent nanocrystals dispersed in said matrix or sol-gel. A number of photo-voltaic solar cells are provided along all of the edges of said transparent sheet, forming the waveguide.

In prior art devices, the luminescent material tend to be incorporated inside the waveguide by mixing the fluorescent material in a polymer plate. The fluorescent material that is embedded in the polymer material, can be either organic (such as organic dyes) or inorganic (such as quantum dots, inorganic phosphors). The waveguide in which the material is embedded may be an inexpensive transparent or translucent sheet or foil of a plastic material, such as poly-methyl-methacrylate (PMMA) or can be simply made out of glass, and acts as a light guide. These devices happen to be relatively prone to reabsorption by the luminescent material due to the distance the photons have to travel inside a luminescent environment. This effect occurs due to the overlap between the absorption and emission spectra of the luminescent molecules. When a photon is emitted in the range of the absorption spectra, there is a chance that the photon gets reabsorbed. The thicker a luminescent waveguide that is used; the greater the chance for a photon to encounter another dye molecule. When the luminescent molecules are embedded in the waveguide, there is a greater chance for a photon to be reabsorbed by another luminescent molecule. In the end, this limits the photon efficiency of these known devices.

It is, inter alia, an object of the present invention to provide a luminescent optical device with a favourable photon efficiency. In a further aspect of the invention it is, inter alia, an object to provide a luminescent ink composition that may be used to attain a favourable photon efficiency.

In order to attain said object of the invention, a luminescent optical device as described in the opening paragraph, according to the invention is characterized in that said luminescent composition comprises a cured ink layer, and in that said polymer matrix comprises a poly-acrylate matrix, particularly a poly-di-acrylate matrix, preferably a poly-glycol di-acrylate matrix. The invention is thereby based on the recognition that an ink may be applied with a relatively low viscosity to provide an extremely thin layer embedding the luminescent material. Such a thin layer reduces the probability that a photos, once re-emitted by a luminescent molecule, will encounter another molecule before reaching the interface with the waveguide. As a result re-absorption is counteracted significantly resulting in an improved photon efficiency of the luminescent part of the device.

The device according to the invention may serve many applications. Particularly the device according to the invention may be used to harvest energy from sunlight by collecting solar radiation at a main surface of said substrate and concentrating at least part of the incident radiation on a smaller surface. Conversely the main surface of the device may also be used as a display or illuminating panel. In view of this, a specific embodiment of the device according to the invention is characterized in that said substrate comprises an at least substantially transparent sheet having a main surface extending between opposite edges of said sheet, said main surface comprising said interface, in that at least one active optical component is coupled optically with at least one of said opposite edges, said optical component being one of a light source and a photo-voltaic converter.

Having a photo-voltaic convertor, often referred to as solar cell, at one of its edges, the device enables the conversion of incident sunlight to electrical energy. Said light is re-emitted by the luminescent composition and guided by the waveguide to the respective edge of the sheet. Conversely, part of light emitted by a light source and coupled into the waveguide at one of the edges of said sheet, may escape from the waveguide to be re-emitted by the luminescent material out of the main surface. The latter may be enhance by creating intentional irregularities at the interface with the waveguide.

The device of the invention will yield a greater output as the surface area of the substrate increases. In this respect large surface areas of facades and windows of existing as well as new buildings provide an excellent opportunity for application of the device according to the invention. In this respect a particular embodiment of the device according to the invention is characterized in that said sheet is at least part of one of: a window pane of a window intended to be used in a facade of a building, a signage element, and a screen intended to be used in a ship, plane or vehicle.

By printing the material as a thin layer, more freedom in design can be achieved which is easier to integrate a luminescent device in urban areas. To achieve a printable thin luminescent layer the material preferably is fluidic while being applied on top of a substrate to be polymerized afterwards to form a thin film. To polymerise a monomeric mixture to form a polymer coating, initiators are added. These molecules are capable of forming very reactive species (radicals) upon a stimulus, which initiates a chain reaction to form a cross-linked macromolecule. These initiators are substances that can produce radical species under certain conditions and promote radical reactions. Subsequently, the initiator radicals will merge with a monomer, which results in the formation of primary radicals that subsequently propagate through additional monomer units to create a polymer network. Acrylates are monomers that easily form polymers because of the double bonds that they possess. These double bonds are very reactive in the presence of radicals.

Oxygen has a significant impact on such photo-polymerization. Oxygen inhibits the polymerization by reacting with the initiator, primary and polymer radicals to form peroxy radicals. The peroxy radicals do not readily and rapidly reinitiate the polymerization. In this way, oxygen scavenges and effectively terminates the radical chain reaction. Oxygen is capable of diffusing into the thin ink layer. As the viscosity of the ink is reduced to promote a thin luminescent layer that is less prone to photon re-absorption, it will be more easy for the oxygen to diffuse into the material. Due to the use of a thin film layer, it is not that difficult for oxygen to penetrate throughout the layer. A method to combat this harmful effect of oxygen is by purging the polymerization environment with an inert gas, like nitrogen. By purging with an inert gas, oxygen is expelled during the polymerization such that the polymerization may continue. However, this solution is less suitable for an industrial scale process, as it requires more expensive and difficult processing conditions.

It is a further object of the invention to provide a luminescent ink composition in which the inhibiting influence of oxygen on a radical initiated polymerization chain reaction is effectively counteracted.

To this end the present invention provides a luminescent ink composition, comprising a polymerizable compound, a polymerization initiator and a luminescence agent, wherein said polymerizable compound comprises an acrylate compound, wherein said polymerization initiator is configured and capable of releasing free radicals during polymerization of said polymerizable compound, and wherein said composition comprises a polymerization promoter that comprises a thiol compound.

A thiol is any organo-sulfur compound of the form R—SH, where R represents an alkyl or other organic substituent. Thiols are the sulfur analogue of alcohols in a sense that sulfur takes the place of oxygen in the hydroxyl group of an alcohol. The addition of thiols to the present luminescent ink composition reduces the inhibiting effects of oxygen. This is due to the hydrogen atom that is taken away from the thiol by the peroxy radicals, whereby a new reactive radical is formed on the thiols. With this composition, any oxygen generated peroxy radicals are neutralized by the thiol molecules such that the polymerization can be performed in the presence of oxygen and the polymer chain reaction is allowed to continue.

In a specific embodiment the ink composition according to the invention is characterized in that said thiol compound is a thiol compound having multiple thiol functional groups. In a preferred embodiment, the ink composition according to the invention is characterized in that said thiol compound comprises 2,2′-(ethylenedioxy)diethanethiol.

In principle several ways are capable of forming initiator radicals for the polymerization reaction, such as chemical, thermal or photo-initiation. Photo-initiators, however, proof desired, as thermal and chemical initiators are often more difficult to control. Accordingly a preferred embodiment of the ink composition according to the invention is characterized in that said polymerization initiator comprises a photo-initiator. The reactive species of the photo-initiators absorb incident light to create initiator radicals. In a further preferred embodiment, the ink composition according to the invention has the feature that said polymerization initiator comprises a at least two photo-initiators that initiate at different wavelengths. Such combination of photo-initiators in the composition results in a faster polymerization process, hence, curing of the ink. Particularly said polymerization initiator may comprise between 0.01 and 15 wt % diphenyl(2,4,6-trimethylbenzoyl)phosphine oxide (TPO), and particularly a mixture of diphenyl(2,4,6-trimethylbenzoyl)phosphine oxide (TPO) and phenylbis(2,4,6-trimethylbenzoyl)phosphine oxide.

The ink composition according to the invention may further comprise a cross-linking agent, particularly di-pentaerythritol penta-acrylate (DPPA) as a cross-linking agent.

For the present invention photo-luminescence is of great importance. Photo-luminescence is the emission of visible light by a material under the stimulus of visible or invisible radiation of shorter wavelengths. In this respect a specific embodiment of the device and ink composition according to the invention are characterized in that said luminescence agent comprises one of a fluorophoric dye, quantum dots (nanocrystals) and phosphors.

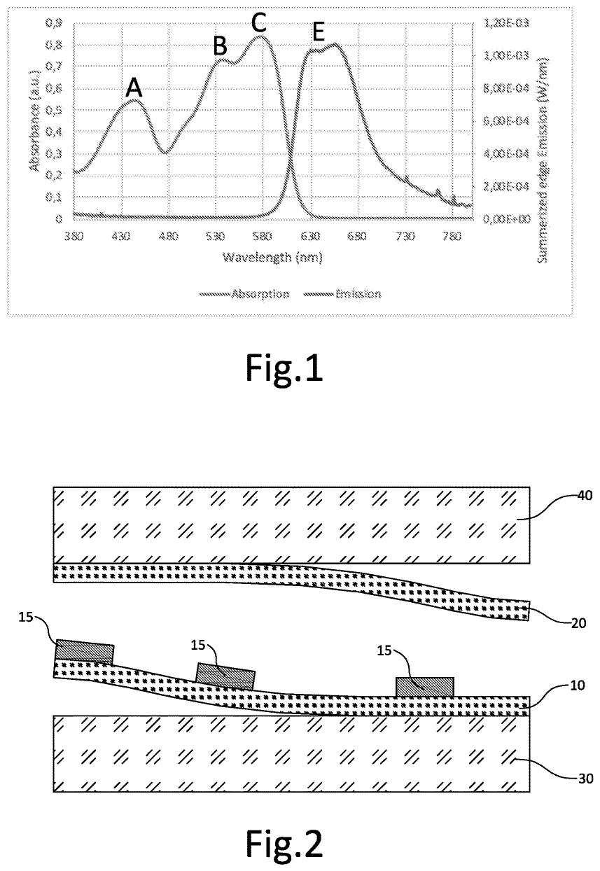

Organic fluorophoric dyes, such as perylene bisimides, are luminescent powders (fluorophores) designed to emit visual light. Although some substances have very broad spectra of excitation and emission, most fluorophores have well-defined bands of excitation and emission. The spectrum in FIG. 1 is an example of an absorption and emission graph for a fluorophore. A good impression at which domain absorption can occur and at which wavelength the light gets emitted is shown in this figure. For both the absorption as emission spectrum, a maximum is shown. This maximum is an indication at which wavelength photons get absorbed most efficiently and at which wavelength the fluorescence is the most intense. The difference between maxima is known as the Stokes shift.

The Stokes shift is one of the factors in a spectrum that gives a good impression of how likely it is for reabsorption to occur. A large Stokes shift between the maxima and a shorter and steeper tail of the spectrum, will results in less reabsorption, as there will be less overlap between the spectra. Reabsorption lowers the efficiency of the LSC as photons have more chance of being redirected outside the waveguide and less photons will reach the solar cells that are mounted on the edges of the device.

A particularly large photon efficiency is reached by a preferred embodiment of the device and ink composition according to the invention that are characterized in that said fluorophoric dye comprises an organic or organo-metallic dye, particularly a dye comprising Perylene-1,6,7,12-tetraphenoxy-3,4,9,10 tetracarboxylic acid-bis-(2′-6′ di-isopropylanilide), more particularly the dye that is commercially available as Lumogen F Red 305 by BASF, a dye comprising benzoxanthene derivative or a perylene perinone based dye. These dyes are capable of absorbing photons in a broad absorption band of 400 to 630 nm. This broad range together with a large stoke shift allow a large number of photons to be absorbed over a large wavelength range, having a reduced probability of being reabsorbed by the dye molecules. This has a significant positive influence on the luminescent efficiency of the device and ink, notably in LSC applications.

With a view on photon efficiency, a preferred embodiment of the device and ink composition are according to the invention characterized in that said acrylate comprises a di-acrylate, preferably a glycol di-acrylate, particularly at least one of tri(propylene glycol)diacrylate (TPGDA), tri(ethylene glycol)diacrylate (TEGDA), 1,6-Hexanediol diacrylate (HDDA) and di(ethylene glycol)diacrylate (DEGDA), wherein most preferably said glycol di-acrylate comprises tri(propylene glycol)diacrylate (TPGDA) or 1,6-Hexanediol diacrylate (HDDA). HDDA appears to be favourable for quantum dots and green dyes based on benzoxanthene, whereas TPGDA favours red dyes like RED-305.

Excellent results are achieved in this sense with a specific embodiment of the ink composition according to the invention wherein the composition comprises between 0.01 and 5 wt %, particularly between 0.01 and 2.5 wt %, more particularly between 0.25 wt % and 1.25 wt %, even more particularly around 1 wt %, of a dye as said luminescence agent and/or wherein the composition comprises between 0.01 and 25 wt %, particularly between 1 wt % and 15 wt %, more particularly around 10 wt %, of quantum dots as said luminescence agent.

In a preferred embodiment said ink composition according to the invention is characterized in that said ink composition has a viscosity in a range of between 1 and 100 mPa·s at an application temperature between 25° C. and 33° C., preferably between 5 and 30 mPa·s at said application temperature. This allows the ink composition to be applied in a thin layer using a thin film deposition technology, like for instance inkjet printing, screen printing, gravure printing, flexographic printing or lithography.

Hereinafter, the invention will be described in further detail with reference to a specific embodiment and an accompanying drawing. In the drawing:

FIG. 1 shows the absorption and emission spectrum of Lumogen F Red 305;

FIG. 2 shows an assembly of a device according to the invention;

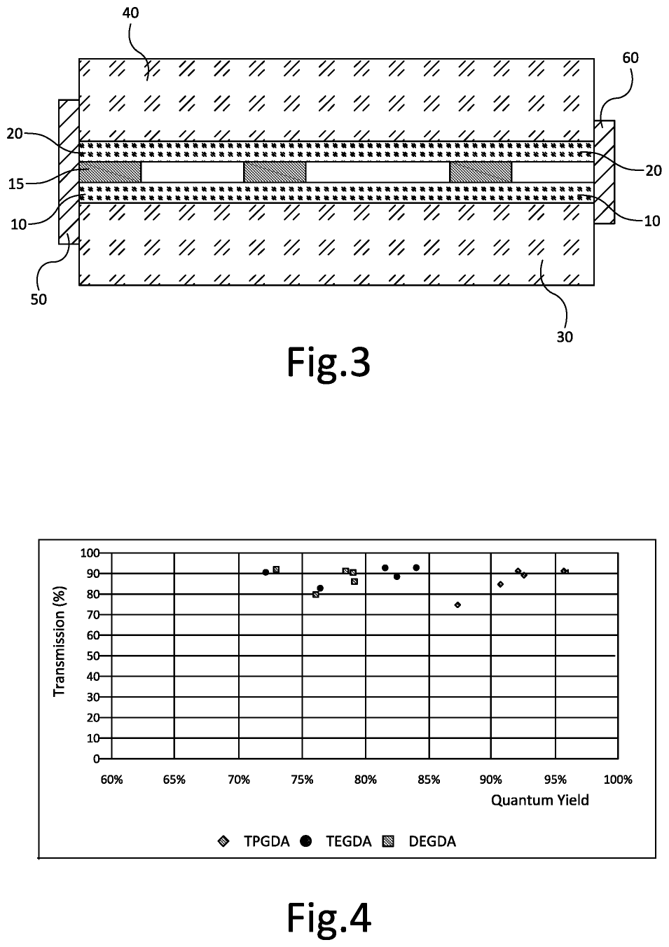

FIG. 3 shows a specific example of a device according to the invention; and

FIG. 4 is a graph of the minimum transmission plotted against the photon efficiency values of selected materials;

It is noted that the figures are drawn purely schematically and not necessarily to a same scale. In particular, certain dimensions may have been exaggerated to a more or lesser extent to aid the clarity of any features. Similar parts are generally indicated by a same reference numeral throughout the figures.

### EXAMPLE

Preparation of the Glycol Diacrylates Fluorescent Ink Compositions

A 1.0 wt % Lumogen F RED 305 fluorescent dye is dissolved in a matrix of 1:6-7 weight mixture of di-pentaerythritol penta-acrylate (DPPA) and one of three glycol di-acrylate monomers: tri(propylene glycol)diacrylate (TPGDA), tri(ethylene glycol)diacrylate (TEGDA) and di(ethylene glycol)diacrylate. Instead of this organic dye (RED305) also quantum dots may be used as a luminescent agent in the coating. The concentration of the dye may vary preferably roughly between 0.01 and 25 wt % for quantum dots and between 0.01 and 2.5 wt % when the aforementioned dye is being used. The di-pentaerythritol penta-acrylate (DPPA) is used as a cross-linker for polymerisation of the glycol di-acrylate monomer compound into the corresponding poly-glycol di-acrylate.

The absorption and emission spectrum of the dye that is used in this example (Lumogen F Red 305) are shown in FIG. 1. This dye is based on perylene bisimides as luminescent agent. The core structure, perylene bisimide, gives an intense fluorescence and photostability, strongly dependent on the substituents. The absorbency of the dye contains three peaks (A,B,C) when the dye is dissolved in a polystyrene matrix. The absorption maxima are found at the wavelengths 442 nm (A), 553 nm (B) and 575 nm (C), with an emission maximum (E) around 640 nm.

To polymerise the monomeric mixture to form a coating, initiators are added. These molecules are capable of forming very reactive species (radicals) upon a stimulus, which initiates a chain reaction to form a cross-linked macromolecule. These initiators produce radical species under certain conditions and promote radical reactions. Next, the initiator radicals will merge with the monomer, which results in the formation of primary radicals that subsequently propagate through additional monomer units to create a polymer network.

Several ways are capable of forming these radicals, such as chemical, thermal or photo-initiation. In this example, however, photo-initiators are applied as the thermal and chemical initiators are more difficult to control and implement in the process. The reactive species created by the photo-initiators are formed by absorbing the incident UV light and photo-cleavage into the initiation of radicals. Two photo-initiators are used that initiate at different wavelengths. This results in a more controlled polymerization process of the coating. Specifically 1.0 wt % Irgacure 819 (bis(2,4,6-trimethyl(benzoyl)-phenylphospineoxide) and 2.5 wt % Irgacure 184 (1-hydroxy-cyclohexyl-phenyl-ketone) are added to the mixture.

Oxygen is found to have a significant impact on the photo-polymerization. Oxygen inhibits the polymerization by reacting with the initiator, primary and polymer radicals to form peroxy radicals. The peroxy radicals do not readily and rapidly reinitiate the polymerization. In this way, oxygen scavenges and effectively terminates radicals. With a view on a rapid solidification and low photon re-absorption, the ink is preferable applied as a relatively thin layer starting with a low velocity. Such layer is especially prone to oxygen diffusing into the layer while it polymerises and cures.

In this example the adverse effect of oxygen during polymerization is counteracted by the addition of one or more thiols to the ink composition, particularly thiols having two or more functional thiol groups. The introduction of thiols reduces the inhibiting effects of oxygen. This is due to the hydrogen atom that is taken away from the thiol by the peroxy radicals, forming a new reactive radical on the thiol. With this technique, the polymerization can be performed even in the presence of oxygen, as the reaction can continue. This renders the ink particularly suitable to be used in industrial processes and on an industrial scale.

In this example the thiols pentaerythritol tetrakis(3-mercaptopropionaat) (PETMP) and 2,2′-(ethylenedioxy)diethanethiol (EDDE) are being added to the ink composition having multiple thiol functional groups for an enhance oxygen suppression. The advantages of using these thiols is that solidification and curing of the ink may be accomplished in open air. The thermal stability increases as the number of mercapto groups increases. Increasing the thiol concentration also increases the solidification rate. The viscosity of the ink preferably below 30 mPa·s. The ink has a viscosity of around 20.8 mPa·s at 25° C. without the dye and initiators, and can be adjusted by changing the composition. At 50° C., the viscosity is around 7.3 mPa·s. The ink compositions for the coatings that are prepared in this example, are summarized in table 1, while their luminescent performance is shown in FIG. 4.

TABLE 1

| | Weight (mg) | | |
|---|---|---|---|
| Component | DEGDA | TEGDA | TPGDA |
| Monomer | 3681.3 | 3679.6 | 3674.1 |
| DPPA | 554.1 | 550.7 | 548.5 |
| Irgacure 819 | 49.7 | 49.8 | 50.1 |
| Irgacure 814 | 125.0 | 124.5 | 124.9 |
| EDDE | 152.9 | 157.2 | 157.3 |
| PETMP | 409.8 | 406.5 | 401.4 |
| L-RED 305 | 49.9 | 50.1 | 50.1 |

Preparation of the Optical Device:

The prepared ink composition may be applied to a suitable substrate in various manners, like spin coating, dipping and lacquering. These techniques are particularly useful for creating a continuous film of the ink, covering substantially the entire surface of the substrate. However, the ink composition of the present example was also found particularly suitable to be used for digital printing techniques, notably ink jet printing. The viscosity of the ink may be tailored to meet the specific printer equipment requirements and specifications by adjusting the amount of cross-linker in the ink. Digital printing techniques are particularly useful for creating specific patters or images on a substrate using the florescent ink composition of the present invention. In either case, the ink may be applied either directly on the substrate or indirectly through an intervening layer or foil. In the latter case the ink is first printed on a suitable carrier, for instance on a flexible foil, that is subsequently transferred to the surface of the substrate while carrying the ink layer or pattern.

In this example the ink 15 is printed on a flexible transparent foil 10 of a suitable plastic, as shown in FIG. 2. Suitable foil 15 materials are for instance poly-vinyl-butyral (PVB) or polyethylene terephthalate (PET). In this example a PVB foil 10 is being used as a first substrate. The ink 15 is printed on the foil 10 in a desired pattern or image with the help of a commercially available inkjet printer by Meyer Burger. Examples of print heads that are capable of depositing the ink are the KM512 MH (16 pL) head by Konica Minolta and the Dimatix Materials Cartridge DMC-11610 (10 pL). Printing the ink can be performed at a ink temperature as low as between 15 and 50° C., specifically around 30° C. This allows a great variety of substrate and foil materials to be used. The printed layer thickness is typically around 30 micron, but may range between 1 and 60 micron, or may even be thicker is so desired. The ink 15 is polymerized by means of a high-intensity UV-lamp (max output 5 W/cm2) underneath the substrate in open air during printing, operating the lamp at between 10 and 20% of its maximum power. The device may be post-cured subsequently, by illumination in an inert nitrogen atmosphere for about 2 minutes at an exposure of around 35 mW/cm2 UV illumination dose.

The foil 10, carrying the ink pattern 15, is subsequently laminated to a transparent substrate 30 as shown in FIG. 2. The substrate 30 is for instance a glass panel or a solid sheet of a translucent/transparent plastic material, like poly-methyl-methacrylate (PMMA), poly-carbonate (PC) or polyethylene terephthalate (PET). Other transparent or translucent substrates are however also feasible to act as a waveguide for photons re-emitted by the ink layer upon excitation by incident primary radiation (light) or for incident light coupled into the waveguide directly from one or more of the edges. In this example two sheets of glass 30,40 are used as solid substrates.

The PVB foil 10 carrying the ink pattern 15 is laminated between the two sheets of glass 30,40 using vacuum at elevated temperature. A second flexible PVB foil 20 is used to protect and seal the ink layer 15 in between the sheets 30,40. This results in a visible print and light concentrating optical assembly, see FIG. 3, of several transparent sheets or layers 10,20,30,40 enclosing a luminescent ink film or pattern 15.

The transparent foils 10,20 and glass sheets 30,40 serve as optical wave guides that capture luminescent radiation emanating from the luminescent ink 15 and guide the radiation to the side edges of the assembly 10.40. Conversely, light that is coupled in at a side edge may be guided by the same wave guides to the ink pattern 15, resulting in luminescence of the ink that is (partly) coupled out at the main surfaces of the assembly to give an illuminating pattern or image. To both ends, active optical components are provided at these side edges to interact with the luminescent pattern 15 or layer. A lights source 50 comprising one or more light emitting diodes is applied at one of the side edges, while a photo-voltaic solar cell 60 is applied at one or more of the other sides of the assemble. Alternatively a light source and converter may also be combined at one or more of the side edges.

Preferably use is made of highly efficient multi junction solar cells to convert light into electricity at at least one of the sides. In this example use is made of thin film flexible CIGS (Copper Indium Gallium Selenide) solar cells. In a practical application the glass sheets 30,40 may have a thickness of the order of a few millimetre and the assembly may advantageously be applied as a component in a window pane for use in a facade of a building to collect solar radiation. A bright light source like a LED or laser device may be used at one of the sides to convert the device into an illuminating surface or specific display.

This renders the device suitable for both illumination/signage applications, wave guiding light from the edges towards the luminescent material, and for harvesting solar energy, capturing incident sunlight and re-emitting photons to the edges where one or more photo-voltaic solar cells are attached. The first application does not in itself require the presence of solar cells, although the combination with solar cells allows the gaining and accumulation of electrical energy from incident sunlight and to use this as an (auxiliary) power source for one or more illuminating light sources. Field of use of such devices may be in auto-motive, signage and building integrated photo-voltaic's.

Performance:

In FIG. 4 the photon efficiencies are shown on the x-axis and the minimum transmission on the y-axis of the different ink composition described above. The different points that can be found in the graph are individual samples that were made by using different spin speeds, ranging from 1000 to 5000 rpm. The ink layer show a transmissivity roughly over 90%, while the photon efficiency ranges between 70% and over 95%. Clearly TPGDA is superior to the other materials in photon efficiency. The highest scores happen to be formed at spin speeds between 3000 and 4000 rpm. Thicker layer may result in lower quantum yield. This may be minimized by using quantum dot material as the luminescent compound. These materials show a quantum yield of between 60 and 80% in an acrylate ink composition according to the invention, which is very high.

Although the invention has been described hereinbefore with reference to merely a number specific examples, it will be appreciated that the present invention is by no means limited to those examples. On the contrary, many other embodiments and variation are feasible to a skilled person within the scope of the present invention.

As an example an luminescent solar concentrator device may also be assembled using fewer, more or other layers than used in the example. Particularly PMMA or poly carbonate (PC) panels may be used instead of the glass panes to save weight. The ink may also be applied directly on one or both of the solid panes in which case these panes will act as an optical wave guide. Also other flexible foils may be used for printing or coating with the ink composition. Particularly a PET foil may be used in this respect for printing. The printed PET foil may be layers with PVB foils at opposite sides while being laminated in between a set of solid transparent substrates.

As far as the luminescent composition is concerned, the invention offers a wide variety of suitable materials. As such, fluorescent dyes can be organic from the classes, but are not limited to: Xanthene derivatives: fluorescein, rhodamine, Oregon green, eosin, and Texas red; Cyanine derivatives: cyanine, indocarbocyanine, oxacarbocyanine, thiacarbocyanine, and merocyanine; Squaraine derivatives and ring-substituted squaraines, including Seta and Square dyes; Squaraine Rotaxane derivatives: SeTau dyes; Naphthalene derivatives (dansyl and prodan derivatives); Coumarin derivatives; oxadiazole derivatives: pyridyloxazole, nitrobenzoxadiazole and benzoxadiazole; Anthracene derivatives: anthraquinones, including DRAQ5, DRAQ7 and CyTRAK Orange; Pyrene derivatives: cascade blue, etc.; Oxazine derivatives: Nile red, Nile blue, cresyl violet, oxazine 170, etc.; Acridine derivatives: proflavin, acridine orange, acridine yellow, etc.; Arylmethine derivatives: auramine, crystal violet, malachite green; Tetrapyrrole derivatives: porphin, phthalocyanine, bilirubin; and perylene derivatives.

Examples of quantum dots are typically made of binary compounds such as: lead sulfide; lead selenide; cadmium selenide; cadmium sulfide; cadmium telluride; indium arsenide; indium phosphide. Quantum dots may also be made from ternary compounds such as cadmium selenide sulfide.

Further, inorganic phosphors may be used as luminescent component, usually consisting of a host material, e.g. an oxide, nitride, oxynitride, silicate, sulfide, selenide, halide or oxyhalide, doped with small amounts of activator ions like rare-earth and/or transition metal ions. Examples include Mn2+, Eu2+ and Ce3+ ions where d-electrons are involved.

1. A luminescent optical device, comprising an optical substrate that provides a wave guide and a luminescent composition that is provided at an interface of said waveguide, wherein said luminescent composition substantially comprises a polymer matrix and a luminescence agent that is dispersed in said polymer matrix, wherein said luminescent composition comprises a cured ink layer, and in that said polymer matrix comprises a poly-acrylate matrix, particularly a poly-di-acrylate matrix, preferably a poly glycol di-acrylate matrix.

2. The luminescent optical device according to claim 1, wherein said substrate comprises at least a substantially transparent sheet having a main surface extending between opposite edges of said sheet, said main surface comprising said interface, in that at least one active optical component is coupled optically with at least one of said opposite edges, said optical component being one of a light source and a photo-voltaic converter.

3. The luminescent optical device according to claim 2, wherein said sheet is at least part of one of: a window pane of a window intended to be used in a facade of a building, a signage element, and a screen intended to be used in a ship, plane or vehicle.

4. The luminescent optical device according to claim 1, wherein said luminescence agent comprises one of a fluorophoric dye, quantum dots (nanocrystals) and phosphors.

5. The luminescent optical device according to claim 4, wherein said fluorophoric dye is one of an organic or organo-metallic dye.

6. The luminescent optical device according to claim 4, wherein said fluorophoric dye comprises Perylene-1,6,7,12-tetraphenoxy-3,4,9,10 tetracarboxylic acid-bis-(2′-6′ di-isopropylanilide), more particularly the fluorophoric dye that is commercially available as Lumogen F Red 305 by BASF.

7. The luminescent optical device according to claim 4, wherein said fluorophoric dye comprises benzoxanthene derivative based dye molecules.

8. The luminescent optical device according to claim 4, wherein said fluorophoric dye comprises perylene perinone based dye molecules.

9. The luminescent optical device according to claim 1, wherein said acrylate comprises a di-acrylate, preferably a glycol di-acrylate, particularly at least one of tri(propylene glycol diacrylate (TPGDA)), tri(ethylene glycol diacrylate (TEGDA)), 1,6-Hexanediol diacrylate (HDDA) and di(ethylene glycol diacrylate (DEGDA)), wherein most preferably said glycol di-acrylate comprises tri(propylene glycol diacrylate (TPGDA) or 1,6-Hexanediol diacrylate (HDDA).

10. The luminescent optical device according to claim 19, wherein the luminescent composition comprises between 0.01 and 25 wt %, particularly between 1 wt % and 20 wt %, more particularly around 10 wt %, of quantum dots as said luminescence agent.

11. The luminescent optical device according to claim 1, wherein the luminescent composition comprises between 0.01 and 5 wt %, particularly between 0.01 and 2.5 wt %, more particularly between 0.25 wt % and 1.25 wt %, even more particularly around 1 wt %, of a dye as said luminescence agent.

12. An illuminating ink composition comprising a polymerizable compound, a polymerization initiator and a luminescence agent, wherein said polymerizable compound comprises an acrylate compound, wherein said polymerization initiator is configured and capable of releasing free radicals during polymerization of said polymerizable compound, and wherein said ink composition comprises a polymerization promoter that comprises a thiol compound.

13. The-An illuminating ink composition according to claim 12, wherein said thiol compound is a thiol compound having multiple thiol functional groups.

14. The illuminating ink composition according to claim 12, wherein said thiol compound comprises 2,2′-(ethylenedioxy)diethanethiol.

15. The illuminating ink composition according to claim 12, wherein said luminescence agent comprises one of a fluorophoric dye, quantum dots and phosphors.

16. The illuminating ink composition according to claim 15, wherein said fluorophoric dye comprises an organic or organo-metallic dye, particularly a dye that is commercially available as RED 305 by BASF, a dye comprising benzoxanthene derivative or a perylene perinone based dye.

17. The illuminating ink composition according to claim 12, wherein said acrylate comprises a di-acrylate, preferably a glycol di-acrylate, particularly at least one of tri(propylene glycol diacrylate (TPGDA)), tri(ethylene glycol diacrylate (TEGDA)), 1,6-Hexanediol diacrylate (HDDA) and di(ethylene glycol diacrylate (DEGDA)), wherein most preferably said glycol di-acrylate comprises tri(propylene glycol diacrylate (TPGDA)) or 1,6-Hexanediol diacrylate (HDDA).

18. The illuminating ink composition according to claim 12, wherein the ink composition comprises between 0.01 and 25 wt %, particularly between 1 wt % and 20 wt %, more particularly around 10 wt %, of quantum dots as said luminescence agent.

19. The illuminating ink composition according to claim 18, wherein the ink composition comprises between 0.01 and 5 wt %, particularly between 0.01 and 2.5 wt %, more particularly between 0.25 wt % and 1.25 wt %, even more particularly around 1 wt %, of a dye as said luminescence agent.

20. The illuminating ink composition according to claim 12, wherein the ink composition comprises a cross-linking agent, particularly di-pentaerythritol penta-acrylate (DPPA).

21. The illuminating ink composition according to claim 12, wherein said polymerization initiator comprises at least one photo-initiator, particularly at least two photo-initiators that initiate at different wavelengths.

22. The illuminating ink composition according to claim 12, wherein said polymerization initiator comprises between 0.01 and 15 wt % diphenyl(2,4,6-trimethylbenzoyl)phosphine oxide (TPO), and particularly a mixture of diphenyl(2,4,6-trimethylbenzoyl)phosphine oxide (TPO) and phenyl bis(2,4,6-trimethylbenzoyl) phosphine oxide.

23. The illuminating ink composition according to claim 12, wherein said ink composition has a viscosity in a range of between 1 and 100 mPa·s at an application temperature between 25° C. and 33° C., preferably between 5 and 30 mPa·s at said application temperature.

24. (canceled)

25. A luminescent optical device comprising:
an optical substrate that provides a wave guide; and
a luminescent composition that is provided at an interface of said waveguide, wherein said luminescent composition comprises a polymerizable compound, a polymerization initiator and a luminescence agent, wherein said polymerizable compound comprises an acrylate compound, wherein said polymerization initiator is configured and capable of releasing free radicals during polymerization of said polymerizable compound, and wherein said luminescent composition comprises a polymerization promoter that comprises a thiol compound.
